(19) United States
(12) Patent Application Publication
(10) Pub. No.: US 2010/0320498 A1
(43) Pub. Date: Dec. 23, 2010

(54) LIGHT-EMITTING DIODE DEVICE

(75) Inventors: Chih-Sheng Lin, Tainan County (TW); Che-Hsiung Wu, Tainan County (TW)

Correspondence Address: MARSH, FISCHMANN & BREYFOGLE LLP, 8055 East Tufts Avenue, Suite 450, Denver, CO, 80237, US

(73) Assignee: UBILUX OPTOELECTRONICS CORPORATION, Tainan County (TW)

(21) Appl. No.: 12/788,157

(22) Filed: May 26, 2010

(30) Foreign Application Priority Data
Jun. 19, 2009 (TW) 098120614

(51) Int. Cl. H01L 33/62

(52) U.S. Cl. 257/99; 257/E33.066

(57) ABSTRACT

A light-emitting diode device includes: a substrate; and a semiconductor layered structure including an n-type semiconductor layer that has an exposed region, and a p-type semiconductor layer that is disposed over the n-type semiconductor layer without extending over the exposed region. An electrode unit is electrically coupled to the semiconductor layered structure, and includes a first electrode and a second electrode. The second electrode has an electrode pad, an end node, and a connecting strip. The electrode pad is larger than the end node. The connecting strip is narrower than the end node.

### CROSS-REFERENCE TO RELATED APPLICATION

This application claims priority of Taiwanese application No. 098120614, filed on Jun. 19, 2009.

### BACKGROUND OF THE INVENTION

1. Field of the Invention

This invention relates to a light-emitting diode device, more particularly to a semiconductor light-emitting diode device.

2. Description of the Related Art

Referring to FIGS. 1 and 2, a conventional semiconductor light-emitting diode device includes a rectangular substrate 11, a semiconductor layered structure 12 formed on the substrate 11, and an electrode unit 13 electrically coupled to the semiconductor layered structure 12. The substrate 11 is made of sapphire, and the semiconductor layered structure 12 is capable of generating light when a working voltage is applied thereto through the electrode unit 13. The semiconductor layered structure 12 includes a n-type semiconductor layer 121 formed on the substrate 11 and having a rectangular exposed region 123, and a p-type semiconductor layer 122 disposed over the n-type semiconductor layer 121 without extending over the rectangular exposed region 123.

The electrode unit 13 has a first electrode 131 disposed on the exposed region 123 and in ohmic contact with the n-type semiconductor layer 121, and a second electrode 132 disposed on and in ohmic contact with the p-type semiconductor layer 122.

However, since the first and second electrodes 131, 132 are opaque, the light generated in the semiconductor layered structure 12 is blocked by the first and second electrodes 131, 132, thereby decreasing the light output power. In addition, the first and second electrodes 131, 132 are rectangular, which has disadvantages of non-uniform current distribution and poor light-emitting efficiency.

Referring to FIGS. 3 and 4, another conventional light-emitting diode device differs from the above-mentioned conventional light-emitting diode device in that a second electrode 132′ thereof has an electrode pad 133, a first extension 134, and a second extension 135. The electrode pad 133 is opposite to a first electrode 131′ and is proximate to a short side 1221′ of the p-type semiconductor layer 122′. The first extension 134 extends from the electrode pad 133 toward the first electrode 131′, and is connected to a center of the second extension 135. By virtue of the symmetrically distributed structural design of the second electrode 132′, a uniform current distribution in the semiconductor layered structure 12′ can be obtained so as to improve the light-emitting efficiency.

Referring to FIGS. 5 and 6, a conventional light-emitting diode device disclosed in U.S. Pat. No. 6,847,052 is substantially similar to the above-mentioned conventional light-emitting diode devices. However, the substrate 11″ is square, and the exposed region 123″ has a sector-shape and is located adjacent to a corner of the substrate 11″. The electrode unit 13′ further includes an electrode layer 138 formed on the p—type semiconductor layer 122″. The second electrode 132″ is formed on the electrode layer 138 and has a central part 136 opposite to the first electrode 131″ and two extension parts 137 extending symmetrically from the central part 136. By virtue of the symmetric configuration of the second electrode 132″, a uniform current distribution can be achieved, thereby increasing light-emitting efficiency of the light-emitting diode device.

### SUMMARY OF THE INVENTION

Therefore, an object of the present invention is to provide a light-emitting diode device that can likewise increase the light-emitting efficiency.

According to the present invention, a light-emitting diode device comprises: a substrate; and a semiconductor layered structure including an n-type semiconductor layer that is formed on the substrate and that has two opposite first sides, two opposite second sides connected between the first sides, and an exposed region proximate to one of the first sides, and a p-type semiconductor layer that is disposed over the n-type semiconductor layer without extending over the exposed region. The p-type semiconductor layer has an intermediate region extending from the exposed region to the other one of the first sides, and opposite first and second regions extending respectively to the second sides from the exposed region and the intermediate region. An electrode unit is electrically coupled to the semiconductor layered structure and includes a first electrode having a first electrode pad disposed on the exposed region of the n-type semiconductor layer, and a second electrode disposed on the p-type semiconductor layer. The second electrode has a second electrode pad disposed on the second region, an end node disposed on the first region, and a connecting strip interconnecting the second electrode pad and the end node and extending across the intermediate region. The second electrode pad is larger than the end node. The connecting strip is narrower than the end node.

### BRIEF DESCRIPTION OF THE DRAWINGS

Other features and advantages of the present invention will become apparent in the following detailed description of the preferred embodiment of this invention, with reference to the accompanying drawings, in which:

FIG. 1 is a plan view of a conventional light-emitting diode device;

FIG. 2 is a schematic view of the conventional light-emitting diode device of FIG. 1;

FIG. 3 is a plan view of another conventional light-emitting diode device;

FIG. 4 is a schematic view of the conventional light-emitting diode device of FIG. 3;

FIG. 5 is a plan view of a conventional light-emitting diode device disclosed in U.S. Pat. No. 6,847,052;

FIG. 6 is a schematic view of the conventional light-emitting diode device of FIG. 5;

FIG. 7 is a plan view of a preferred embodiment of a light-emitting diode device according to this invention;

FIG. 8 is a schematic view of the preferred embodiment taken along line VIII-VIII in FIG. 7;

FIG. 9 is a plot of a length ratio versus light output power of the preferred embodiment;

FIG. 10 is a plot of a chip size versus light output power of the preferred embodiment and Comparative Examples 1 and 2; and

FIG. 11 is a plot of a distance ratio versus light output power of the preferred embodiment.

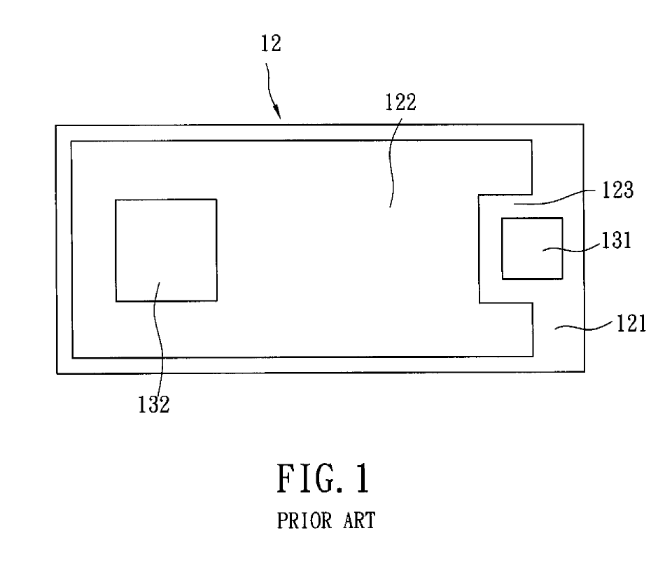

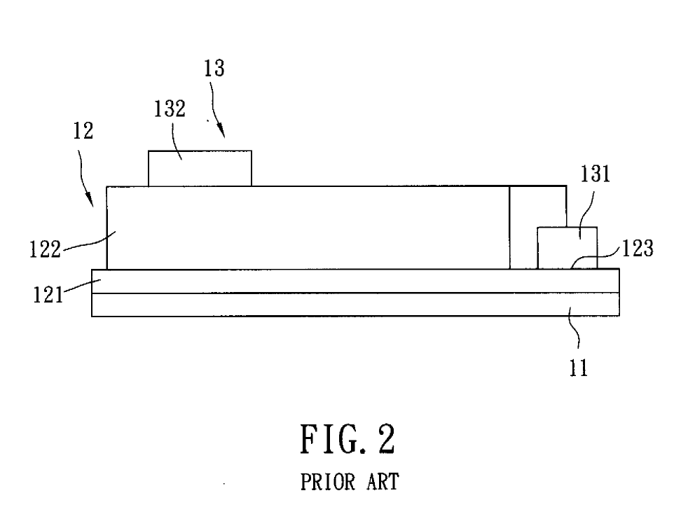

### DETAILED DESCRIPTION OF THE PREFERRED EMBODIMENT

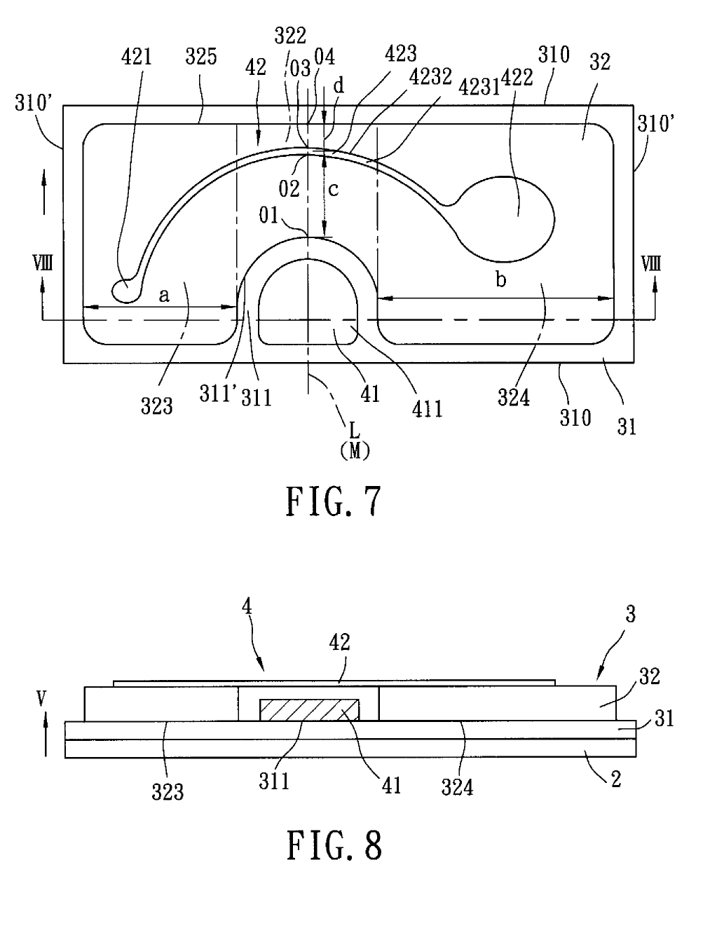

Referring to FIGS. 7 and 8, alight-emitting diode device of a preferred embodiment according to this invention includes a substrate 2, a semiconductor layered structure 3, and an electrode unit 4. The semiconductor layered structure 3 is capable of generating light when a working voltage is applied thereto through the electrode unit 4.

The substrate 2 is made of an insulating material. In this embodiment, the substrate 2 is made of sapphire and is rectangular in shape.

The semiconductor layered structure 3 includes an n-type semiconductor layer 31 that is formed on the substrate 2 and that has two opposite first sides 310, two opposite second sides 310′ connected between the first sides 310, and an exposed region 311 proximate to one of the first sides 310, and a p-type semiconductor layer 32 that is disposed over the n-type semiconductor layer 31 without extending over the exposed region 311.

The p-type semiconductor layer 32 has an intermediate region 322 extending from the exposed region 311 to the other one of the first sides 310, and opposite first and second regions 323, 324 extending respectively to the second sides 310′ from the exposed region 311 and the intermediate region 322.

Preferably, a ratio of the length (a) of the first region 323 to the length (b) of the second region 324 along a line parallel to the first sides 310 ranges from 0.6 to 0.95.

In this embodiment, the n-type semiconductor layer 31 is rectangular and corresponds in shape to the substrate 2. The first sides 310 are longer than the second sides 310′. The exposed region 311 has a rounded shape and is confined by a concaved wall 311′ which is opened at the first side 310 proximate thereto.

The n-type and p-type semiconductor layers 31, 32 are formed by epitaxial growth techniques. After formation of the p-type semiconductor layer 32 on the n-type semiconductor layer 31, portions of the p-type semiconductor layer 32 are etched using lithography techniques until parts of the n-type semiconductor layer 31 are exposed. The exposed parts of the n-type semiconductor layer 31 include the rounded exposed region 311.

The n-type and p-type semiconductor layers 31, are made of semiconductor materials that respectively include n-type and p-type dopants containing Group III-V elements. In this embodiment, the n-type and p-type semiconductor materials are gallium nitride-based semiconductors.

Moreover, the semiconductor layered structure 3 can include various layered structures depending on actual requirements. For example, the semiconductor layered structure 3 may further include a conductive layer formed on the p-type semiconductor layer 32 to facilitate a uniform current flow, thereby improving the light-emitting efficiency.

The electrode unit 4 is electrically coupled to the semiconductor layered structure 3 and includes a first electrode 41 that has a first electrode pad 411 disposed on and in ohmic contact with the rounded exposed region 311 of the n-type semiconductor layer 31, and a second electrode 42 disposed on and in ohmic contact with the p-type semiconductor layer 32. The second electrode 42 has a second electrode pad 422 disposed on the second region 324, an end node 421 disposed on the first region 323, and a connecting strip 423 interconnecting the second electrode pad 422 and the end node 421. In this embodiment, the first electrode pad 411 is centrally disposed on the rounded exposed region 311, and the connecting strip 423 extends across the intermediate region 322 and is concaved substantially in the same direction as the concaved wall 311′. The second electrode pad 422 is larger than the end node 421, and the connecting strip 423 is narrower than the end node 421.

It is noted that by controlling a position of the connecting strip 423, the light-emitting efficiency of the light-emitting diode device can be increased.

In this embodiment, the rounded exposed region 311 is symmetric with respect to a center line (L) that is parallel to the second sides 310′ and that extends centrally through the rounded exposed region 311. The connecting strip 423 has first and second curved edges 4231, 4232 extending from the second electrode pad 422 to the end node 421. The first curved edge 4231 is proximate to the concaved wall 311′, and the second curved edge 4232 is distal from the concaved wall 311′. The p-type semiconductor layer 32 has a lateral edge 325 parallel to the first sides 310 of the n-type semiconductor layer 31 and proximate to the second curved edge 4232. The concaved wall 311′, the first and second curved edges 4231, 4232, and the lateral edge 325 of the p-type semiconductor layer 32 intersect a common intersection line (M) at first, second, third and fourth points 01, 02, 03, 04, respectively. The common intersection line (M) is parallel to the center line (L) and is aligned therewith along a direction (V) that is substantially perpendicular to the semiconductor layered structure 3. A ratio of a distance (c) between the first and second points 01, 02 to a distance (d) between the third and fourth points 03, 04 ranges from 1.5 to 4.0.

Preferably, the first and second electrodes 41, 42 are made of a metal material selected from the group consisting of gold, aluminum, palladium, titanium, platinum, and alloys thereof. In this embodiment, the first and second electrodes 41, 42 are made of platinum.

### First Experiments

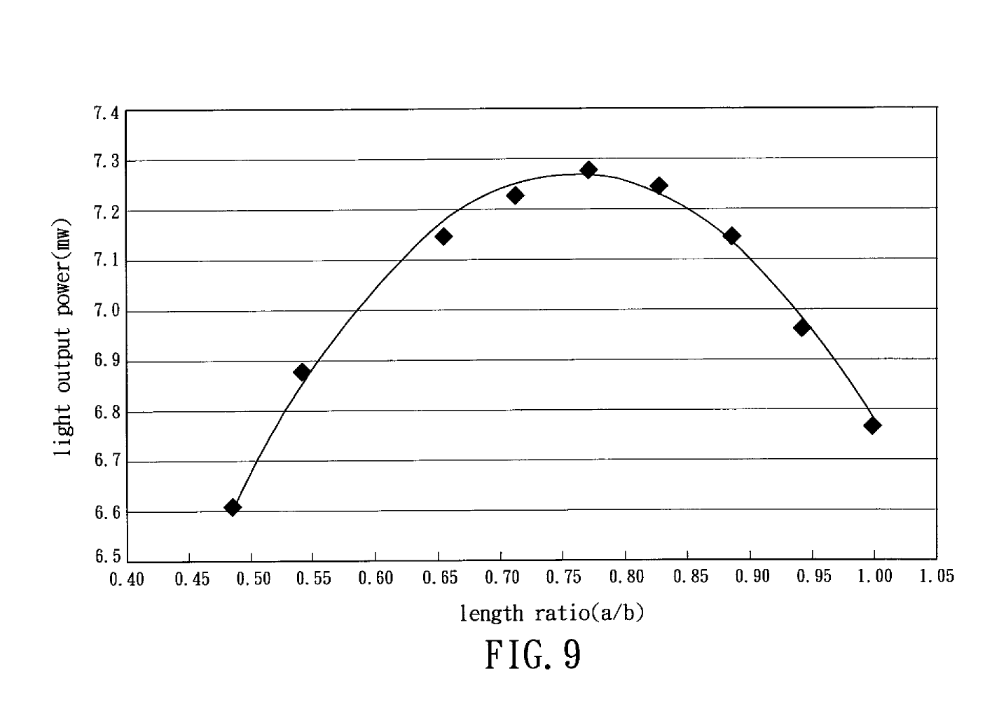

FIG. 9 is a plot of the ratio (a/b) versus light output power of the preferred embodiment. The ratio (c/d) of the distance between the first and second points to the distance between the third and fourth points is 3.0, and a constant working voltage is applied to the light-emitting diode device throughout the experiments. The results of the experiments show that, when the ratio (a/b) of the length (a) of the first region 323 to the length (b) of the second region 324 is controlled to range from 0.6 to 0.95, the light-emitting diode device has a light output power larger than 7.0 mW. The experiments further exhibit that, when the ratio (a/b) ranges from 0.65 to 0.9, the light output power can be increased to a value larger than 7.1 mW.

### Second Experiments

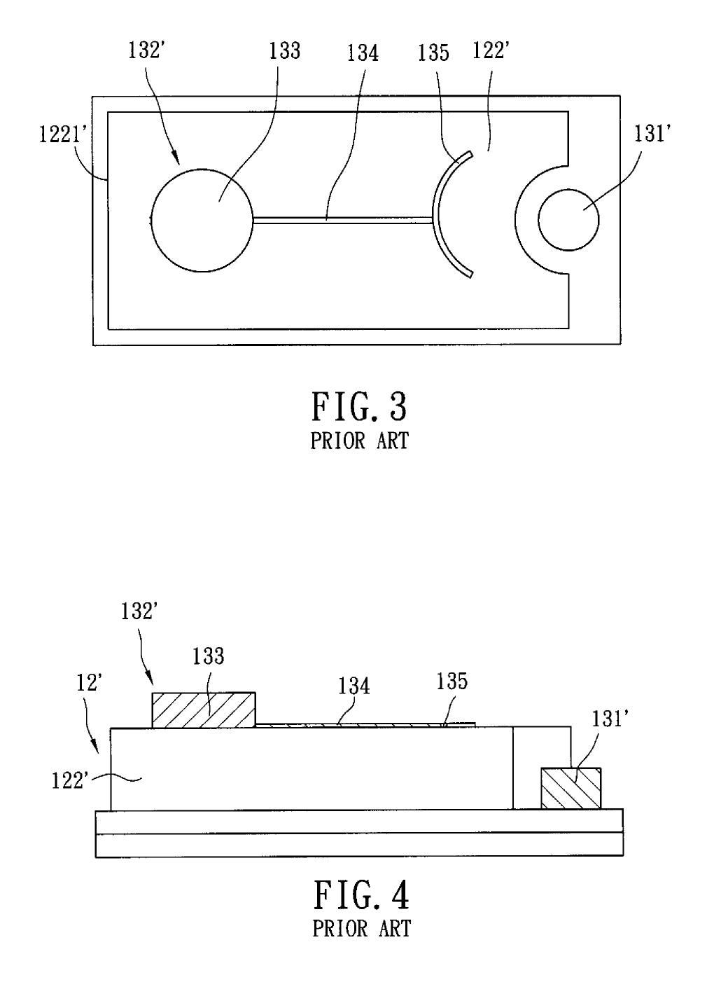

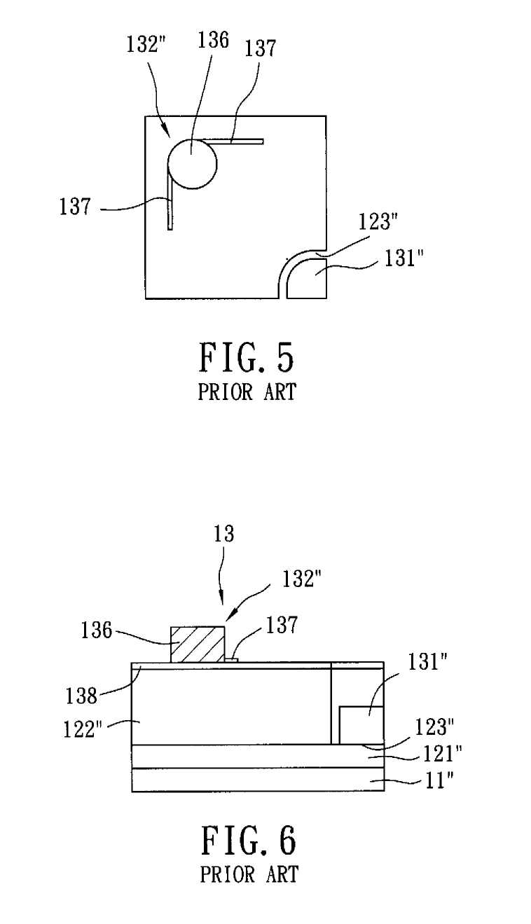

Referring to Table 1, Example 1 (E1) is the light-emitting diode device of the preferred embodiment in which the ratio (a/b) is 0.71 and the ratio (c/d) is 3, and Comparative Examples 1 and 2 (CE1, CE2) are the light-emitting diode devices shown in FIGS. 3 and 5, respectively. Table 1 shows the results of the experiments using different chip sizes but applying the same working voltage.

TABLE 1

| | | | Light output |
|---|---|---|---|
| | Chip size | Area | power |
| | (μm × μm) | (μm²) | (mW) |
| E1 | 8 × 16 | 128 | 6.61 |
| | 8.5 × 16.8 | 142.8 | 6.82 |
| | 10 × 18.1 | 181 | 7.17 |
| | 9.3 × 17.1 | 159.03 | 6.91 |
| | 10 × 19 | 190 | 7.29 |
| CE1 | 10 × 23 | 230 | 6.75 |
| | 10 × 20 | 200 | 6.63 |
| | 10 × 18 | 180 | 6.44 |
| | 10 × 14 | 140 | 6.32 |
| | 10 × 12 | 120 | 6.17 |
| CE2 | 10 × 10 | 100 | 6.32 |
| | 12 × 12 | 144 | 6.69 |
| | 14 × 14 | 196 | 6.91 |
| | 15 × 15 | 225 | 7.02 |
| | 16 × 16 | 256 | 7.11 |

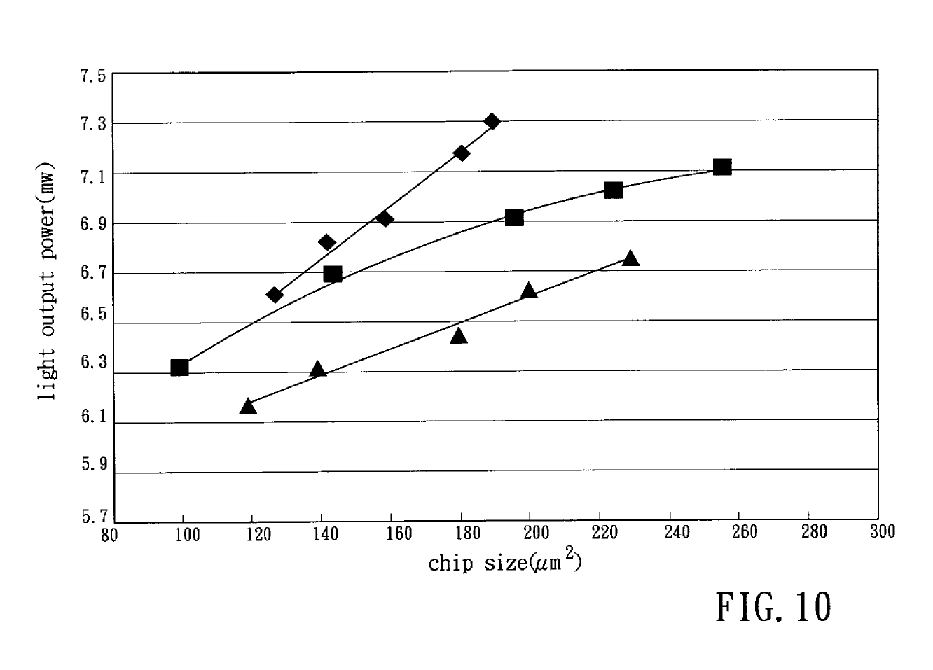

FIG. 10 is a plot of chip size versus light output power derived from the data of Table 1. The result of Example 1 is represented by rhombus (♦), and those of Comparative Examples 1 and 2 are respectively represented by triangle (▴) and square (▪). The plot shows that a uniform current distribution is obtained in Example 1 which has the second electrode 42 provided with an asymmetric electrode configuration and which has a particular ratio (a/b) of the length of the first region 323 to the length of the second region 324. In addition, when the chip sizes for Example 1 and Comparative Examples 1 and 2 are the same, the light-emitting efficiency of Example 1 of the preferred embodiment is the highest, and a desired light emission brightness thereof can also be achieved within a short reaction time. Therefore, the light-emitting diode device of the preferred embodiment with a smaller chip size has the same light output power as compared to that of a conventional light-emitting diode device, thereby decreasing costs and chip sizes.

### Third Experiments

The third experiments are performed to show that when the ratio (c/d) of a distance between the first and second points 01, 02 to a distance between the third and fourth points 03, 04 ranges from 1.5 to 4.0, the light-emitting efficiency can be enhanced.

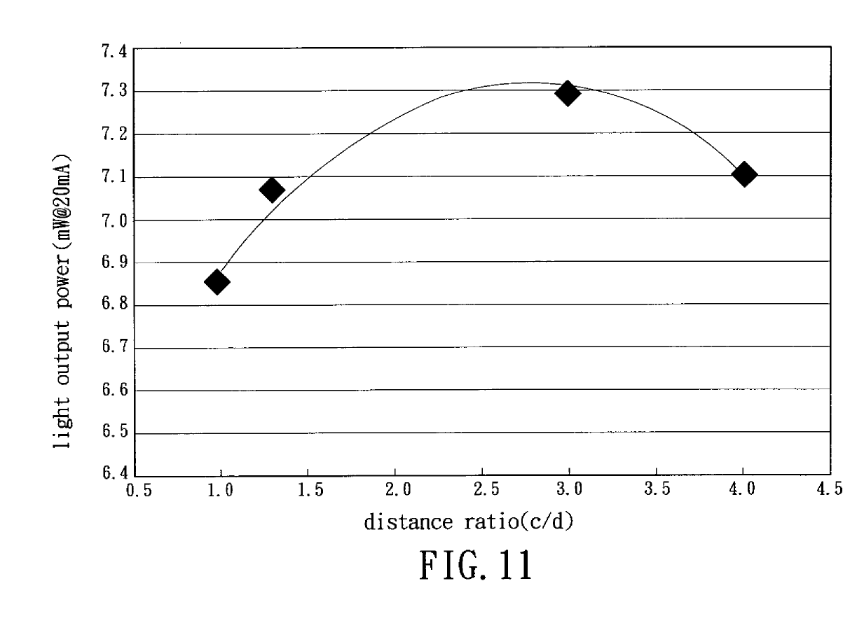

Referring to FIG. 11, a plot of the ratio (c/d) versus light output power of the preferred embodiment is shown. The ratio (a/b) of the length of the first region 323 to the length of the second region 324 is 0.71 in the preferred embodiment. The plot shows that, when the ratio (c/d) ranges from 1.5 to 4.0, the light-emitting diode device has the light output power of at least 7.1 mW. When the ratio (c/d) ranges from 2 to 3.5, the light output power can be increased to a value of 7.2 mW.

With the invention thus explained, it is apparent that various modifications and variations can be made without departing from the spirit of the present invention. It is therefore intended that the invention be limited only as recited in the appended claims.

What is claimed is:

1. A light-emitting diode device comprising:
a substrate;
a semiconductor layered structure including an n-type semiconductor layer that is formed on said substrate and that has two opposite first sides, two opposite second sides connected between said first sides, and an exposed region proximate to one of said first sides, and a p-type semiconductor layer that is disposed over said n-type semiconductor layer without extending over said exposed region, said p-type semiconductor layer having an intermediate region extending from said exposed region to the other one of said first sides, and opposite first and second regions extending respectively to said second sides from said exposed region and said intermediate region; and
an electrode unit electrically coupled to said semiconductor layered structure and including a first electrode having a first electrode pad disposed on said exposed region of said n-type semiconductor layer, and a second electrode disposed on said p-type semiconductor layer, said second electrode having a second electrode pad disposed on said second region, an end node disposed on said first region, and a connecting strip interconnecting said second electrode pad and said end node and extending across said intermediate region, said second electrode pad being larger than said end node, said connecting strip being narrower than said end node.

2. The light-emitting diode device of claim 1, wherein a ratio of the length of said first region to the length of said second region along a line parallel to said first sides ranges from 0.6 to 0.95.

3. The light-emitting diode device of claim 1, wherein said first sides are longer than said second sides.

4. The light-emitting diode device of claim 1, wherein said exposed region is rounded and is confined by a concaved wall which is opened at said one of said first sides, said exposed region being symmetric with respect to a center line parallel to said second sides and extending centrally through said exposed region, said connecting strip being concaved substantially in the same direction as said concaved wall.

5. The light-emitting diode device of claim 4, wherein said connecting strip has first and second curved edges extending from said second electrode pad to said end node, said first curved edge being proximate to said concaved wall, and a second curved edge being distal from said concaved wall, said p-type semiconductor layer having a lateral edge parallel to said first sides of said n-type semiconductor layer and proximate to said second curved edge, said concaved wall, said first and second curved edges, and said lateral edge of said p-type semiconductor layer intersecting a common intersection line at first, second, third and fourth points, respectively, said common intersection line being parallel to said center line and aligned with said center line along a direction perpendicular to said semiconductor layered structure, a ratio of a distance between said first and second points to a distance between said third and fourth points ranging from 1.5 to 4.0.

6. The light-emitting diode device of claim 5, wherein a ratio of the distance between said first and second points to the distance between said third and fourth points ranges from 2.0 to 3.5.
